(19) United States
(12) Patent Application Publication
(10) Pub. No.: US 2026/0334250 A1
(43) Pub. Date: Oct. 22, 2026

(54) THREE-DIMENSIONAL PACKAGING STRUCTURE AND MANUFACTURING METHOD THEREFOR

(71) Applicant: SJ Semiconductor(Jiangyin) Corporation, Jiangyin (CN)

(72) Inventors: Yenheng CHEN, Jiangyin (CN); Chengchung LIN, Jiangyin (CN)

(73) Assignee: SJ Semiconductor(Jiangyin) Corporation, Jiangyin, JS (CN)

(21) Appl. No.: 19/107,592

(22) PCT Filed: Jun. 1, 2023
(86) PCT No.: PCT/CN2023/097801

§ 371 Date: Feb. 28, 2025

(30) Foreign Application Priority Data
Sep. 2, 2022 (CN) 202211068311.2

(51) Int. Cl. H10W 70/60; H10W 40/20; H10W 70/00; H10W 70/05; H10W 70/06; H10W 90/10

(52) U.S. Cl. CPC H10W 70/616; H10W 70/06; H10W 90/10; H10W 40/233; H10W 40/235; H10W 70/099

(57) ABSTRACT

A three-dimensional encapsulation structure and a method are disclosed. The structure comprises: a package substrate, a rewiring layer, TSV bridging substrates, chips and a laminate layer. The rewiring layer is disposed on an upper surface of a package substrate; TSV bridging substrates are disposed on an upper surface of the rewiring layer; the chips are disposed on an upper surface of the TSV bridging substrates; and a layer of laminate material is formed on an upper surface of the rewiring layer. The three-dimensional packaging structure and its preparation method solve the problem of high cost and low yield caused by interconnecting heterogeneous chips and the one-piece TSV intermediary substrate to the packaging substrate in the existing packaging technology.

### TECHNICAL FIELD

The present invention relates to the field of semiconductor packaging, and in particular to a three-dimensional packaging structure and its preparation method.

### BACKGROUND

Usually, end-users want their devices to be smaller, faster, more energy-efficient, and higher-performance, encapsulating more functionality in a single wafer will become an important trend in the future of semiconductor packaging. SiP (System In a Package) is a system level package that assembles two or more heterogeneous semiconductor chips and passive components together to form a standard package that implements a specific function. Architecturally, SiP integrates multiple functional chips, including processors, memory, and other functional wafers into a single package, thus realizing an essentially complete function.

SiP often has multiple heterogeneous chips arranged in an array, they rely on TSV interposer (a substrate as an intermediary layer containing silicon vias) located on the lower side of the chips to realize high-density interconnections and complete many operations and data exchanges, which saves power and increases bandwidth.

Because the TSV interposer has high density of solder bumps placed at high precision, those through-holes are made with diameters between 1 μm-50 μm, which makes the production yield challenging, often the larger the area of the TSV interposer is, the lower the yield becomes, driving high the cost of SIP substrate using a full piece intermediary layer.

In addition, electrical signal transmission between these heterogeneous chips and external circuits relies on the package substrate located on the lower side of the TSV intermediary layer substrate. Compared to the high-density interconnection realized by the TSV intermediary layer substrate, the package substrate realizes low-density interconnection, and the connection lines and solder joints (e.g., C4 solder joints) inside it are not as dense as those inside the TSV intermediary layer substrate (e.g., C2 solder joints), and the low-density package substrate directly bonds with the high-density TSV intermediary layer substrate to meet the connection requirements. Low-density package substrate and high-density TSV intermediary layer substrate direct bonding connection, the package substrate must have a lot of interconnection layer, in order to meet the demand for connection, and the more the number of layers of the package substrate, the lower the production yield, the higher the cost; and, in order to make the package substrate solder joints and TSV intermediary layer substrate solder joints bonding, it is inevitable that the package substrate solder joints are designed to be very dense, which further This further increases the production cost of the package substrate.

### SUMMARY

The present invention provides a three-dimensional packaging structure and a preparation method thereof, to solve the problems of increased cost and lower yield caused by interconnecting heterogeneous chips and the one-piece TSV intermediary substrate to the packaging substrate in the existing packaging technology.

The present invention provides a method of preparing a three-dimensional encapsulated structure, the method of preparation comprising:
S1, providing a temporary carrier board with a rewiring layer formed on an upper surface of the temporary carrier board;
S2, providing a plurality of TSV bridging substrates, bonding the plurality of the TSV bridging substrates to the rewiring layer;
S3, forming a first plasticized layer on an upper surface of the rewiring layer, the first plasticized layer exposing solder joints of the TSV bridging substrate;
S4, providing a plurality of chips, bonding the plurality of the chips to the plurality of the TSV bridging substrates;
S5, forming a second plasticized layer on the upper surface of the first plasticized layer;
S6, removing the temporary carrier board and forming a rewiring layer solder joint on a surface of the rewiring layer away from the TSV bridge substrate;
S7, providing a package substrate and bonding the rewiring layer to the package substrate via the rewiring layer solder joints.

Optionally, the method of preparing the rewiring layer described in S1 comprises:
S11, a first mask layer having a first opening pattern is formed on the upper surface of the temporary carrier board;
S12, forming a first metal pattern layer based on the first opening pattern;
S13, removing the first mask layer and forming a second mask layer having a second opening pattern on the first metal pattern layer, the second opening pattern exposing at least a portion of the upper surface of the first metal pattern layer;
S14, forming a first metal column layer based on the second opening pattern;
S15, removing the second mask layer and forming a first dielectric layer on the upper surface of the temporary carrier board, the first dielectric layer encompassing the first metal pattern layer and the first metal column layer; and
S16, grinding the first dielectric layer until an upper surface of the first metal column layer is exposed.

Optionally, the method of preparing the rewiring layer further comprises: s17, repeating steps S11~S16 at least once to prepare and obtain a plurality of layers of the rewiring layer.

Optionally, prior to S11, the method of preparing the rewiring layer further comprises: a step of S10, forming a metal seed layer on the upper surface of the temporary carrier board; at this point, after removing the second mask layer in S15, prior to forming the first dielectric layer, a step of removing a metal seed layer that is not covered by the first metal pattern layer is also included.

Optionally, the step of forming a release layer on the upper surface of the temporary carrier board before forming a rewiring layer on the upper surface of the temporary carrier board in S1 includes the step of forming a release layer on the upper surface of the temporary carrier board; at this point, the step of removing the release layer when removing the temporary carrier board in S6 includes the step of removing the release layer.

Optionally, after bonding the plurality of the TSV bridging substrates to the rewiring layer in S2, further comprising the step of filling the gap in which the plurality of the TSV bridging substrates is bonded to the rewiring layer with a laminate layer;

S4 after bonding the plurality of the chips to a plurality of the TSV bridging substrates, further comprising the step of filling of a laminate layer within a gap between a plurality of the chips and a plurality of the TSV bridging substrates;

S7 after bonding the rewiring layer to the package substrate, further comprising the step of filling a laminate layer within a gap where the rewiring layer is bonded to the package substrate.

Optionally, the method of preparation further comprises: S8, the step of providing a heat sink on a surface of the package substrate connecting the rewiring layer, wherein the heat sink encases a plurality of the chips therein.

Optionally, the three-dimensional encapsulated structure comprises:
a packaging substrate, a rewiring layer, a plurality of TSV bridging substrates, a plurality of chips and a plasticized sealing layer; wherein the
the rewiring layer is disposed on an upper surface of the package substrate which is bonded to the package substrate;
a plurality of the TSV bridging substrates is disposed on an upper surface of the rewiring layer which is bonded to the rewiring layer;
a plurality of the chips is disposed on an upper surface of a plurality of the TSV bridging substrates which are bonded to the plurality of the TSV bridging substrates; and
the layer of plasticized material is formed on the upper surface of the rewiring layer which encases a plurality of the TSV bridge substrates and a plurality of the chips.

Optionally, the three-dimensional packaging structure further comprises a heat sink plate provided on an upper surface of the packaging substrate, encasing a plurality of the chips therein.

Optionally, the three-dimensional packaging structure further comprises a laminate layer formed within a gap wherein the plurality of the TSV bridging substrates are by bonding connected to the rewiring layer, the plurality of the chips are by bonding connected to the plurality of the TSV bridging substrates, and a gap wherein the rewiring layer is by bonding connected to the packaging substrate.

As described above, the three-dimensional encapsulated structure of the present invention and the method of preparing it, the
1, the use of a number of smaller TSV bridge substrate instead of the whole TSV intermediate layer substrate to achieve high-density interconnection between different chips, without affecting the interconnection function on the basis of the TSV bridge substrate can increase the production yield and reduce costs;
2, high connection density TSV bridge substrate is first connected with medium connection density heavy wiring layer, and then the heavy wiring layer is connected with the lower density package substrate, so that the number of interconnecting layers inside the package substrate is reduced, and the risk of low yield of multi-layer substrate production is avoided;
3, the new process of production of heavy wiring layer, the production of the formation of heavy wiring layer flatness is good, high reliability of signal transmission.

### BRIEF DESCRIPTION OF THE DRAWINGS

FIG. 1 shows a flowchart of a method of preparing a three-dimensional encapsulated structure according to in the present invention.

FIG. 2 shows a flowchart of a method of preparing a rewiring layer according to the present invention.

FIG. 3 shows a schematic view of the structure of the present invention after the formation of the release layer according to the present invention.

FIG. 4 shows a schematic view of the structure of the metal seed layer after it has been formed according to the embodiments of the present invention.

FIG. 5 shows a schematic view of a structure after forming the first mask layer as described in the present invention.

FIG. 6 shows a schematic view of a structure after forming the first metal pattern layer according to the present invention.

FIG. 7 shows a schematic view of the structure described in the present invention after removal of the first mask layer.

FIG. 8 shows a schematic view of the structure of the second mask layer after it has been formed according to the present invention.

FIG. 9 shows a schematic view of the structure of the first metal column layer after it has been formed according to the present invention.

FIG. 10 shows a schematic view of a structure according to an embodiment of the present invention after removal of the second mask layer and the metal seed layer.

FIG. 11 shows a schematic view of a structure after forming the first dielectric layer according to the present invention.

FIG. 12 shows a schematic view of the structure after thinning the first dielectric layer according to the present invention.

FIG. 13 shows a schematic view of a structure after forming a multilayer rewiring layer according to the present invention.

FIG. 14 shows a schematic view of the structure of the TSV bridge substrate after bonding it to the rewiring layer according to the present invention.

FIG. 15 shows a schematic view of a structure after forming the first plasticized layer according to an embodiment of the present invention.

FIG. 16 shows a schematic view of a structure after thinning the first plastic sealing layer according to the embodiments of the present invention.

FIG. 17 shows a schematic view of the structure of the chip after bonding it to the TSV bridge substrate as described in the present invention.

FIG. 18 shows a schematic view of a structure after forming the second plasticized layer as described in embodiments of the present invention.

FIG. 19 shows a schematic view of a structure after thinning the second plastic sealing layer according to the embodiments of the present invention.

FIG. 20 shows a schematic view of the structure described in the present invention with the temporary carrier board removed.

FIG. 21 shows a schematic view of the structure of the protective layer after it has been formed according to the embodiments of the present invention.

FIG. 22 shows a schematic view of a structure after forming a protective layer mask layer according to an embodiment of the present invention.

FIG. 23 shows a schematic view of the structure of the rewiring layer after forming the solder joints according to the present invention.

FIG. 24 shows a schematic view of the structure of the rewiring layer described in the present invention after it has been bonded to the package substrate.

FIG. 25 shows a schematic view of the structure of the present invention described herein after it has been filled with the layer of laminate.

FIG. 26 shows a schematic view of the structure after the provision of the heat sink according to the present invention.

### REFERENCE NUMERALS

10 three-dimensional package structure
110 temporary carrier
111 release layer
101 Heavy wiring layer solder joints
112 protective layer
113 shutter
114 solder mask layer
115 decals
100 rewiring layer
121 first mask layer
122 Second mask layer
130 metal seed layer
140 first metal pattern layer
150 first metal column layer
160 first dielectric layer
200 TSV Bridge Substrate
300 laminate
310 first plasticized sealing layer
320 second plasticized sealing layer
400 microchip
410 Type I chips
420 Type II chips
500 package substrate
600 heat sink
700 filler material layer

### DETAILED DESCRIPTION OF THE PREFERRED EMBODIMENTS

Embodiments of the present invention are hereinafter described by way of particular specific examples, and other advantages and efficacies of the present invention can be readily appreciated by those skilled in the art from what is disclosed in this specification. The present invention may also be implemented or applied in different other specific embodiments, and various details in this specification may also be modified or changed in various ways based on different views and applications without departing from the spirit of the present invention.

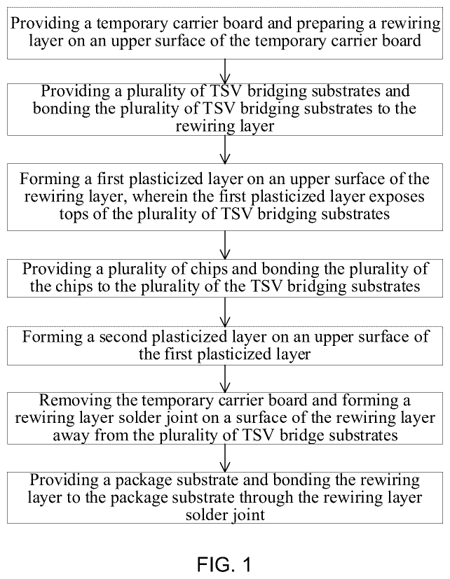

Refer to FIGS. 1 through 26. It is to be noted that the illustrations provided in this embodiment only illustrate the basic concept of the present invention in a schematic manner, and only the components related to the present invention are shown in the illustrations, which are not drawn in accordance with the number, shape, and size of the components in actual implementation, and the actual implementation of the components, the number, and the proportion of the components may be changed arbitrarily, and the layout of the components may also be more complex.

The present embodiment provides a method of preparing a three-dimensional encapsulated structure 10, as shown in FIG. 1, the method of preparing the three-dimensional encapsulated structure 10 comprising: step S1)~step S7). Specifically, step S8) is also included.

Step S1): providing a temporary carrier board 110, forming a rewiring layer 100 on the upper surface of the temporary carrier board 110.

In this embodiment, the temporary carrier board 110 may be a glass carrier plate, a ceramic carrier plate, etc.

Specifically, as shown in FIG. 3, a release layer 111 is formed on the upper surface of the temporary carrier board 110 before forming a rewiring layer 100 on the upper surface of the temporary carrier board 110.

In this embodiment, the upper surface of the release layer 111 corresponds to the upper surface of the temporary carrier board 110, i.e., the rewiring layer 100 is formed on the upper surface of the release layer 111; the release layer 111 can be formed on the temporary carrier board 110 by, e.g., spin-coating; the release layer 111 can be formed by an adhesive, e.g., a UV adhesive, a photo-thermal converting adhesive, or the like; the release layer 111 can break down by the action of light and heat, and thus can be detached from the temporary carrier board 110 in a subsequent step. action to disintegrate, whereby the temporary carrier board 110 may be detached from the overlay structure formed in a subsequent step.

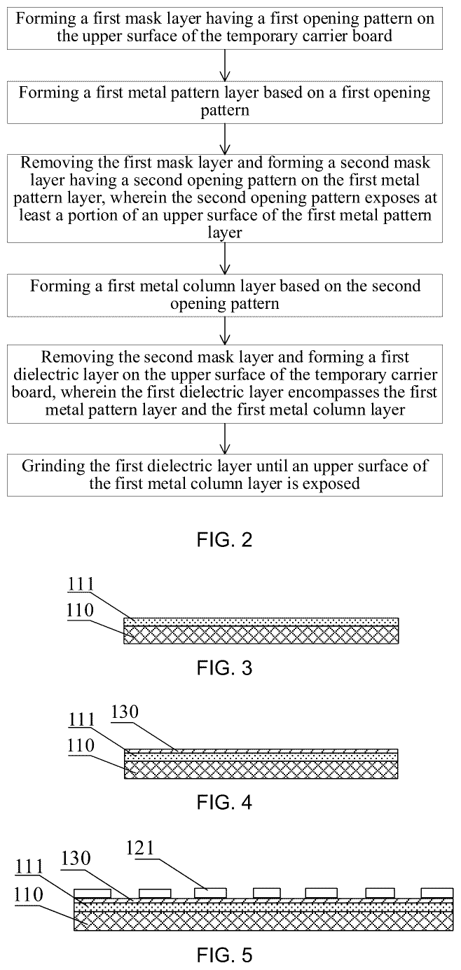

Specifically, as shown in FIG. 2, the method of preparing the rewiring layer 100 comprises: steps S11)~steps S16). More specifically, steps S10) and S17) are also included.

Step S10): forming a metal seed layer 130 on the upper surface of the temporary carrier board 110 as shown in FIG. 4.

In this embodiment, the metal seed layer 130 covers the upper surface of the release layer 111; the metal seed layer 130 may be formed using sputtering or a suitable technique; it is noted that the metal seed layer 130 may comprise a first metal layer and a second metal layer disposed on top of the first metal layer, the first metal layer being, for example, a titanium layer and the second metal layer being, for example, a copper layer.

Step S11): forming a first mask layer 121 with a first opening pattern on the upper surface of the temporary carrier 110 as shown in FIG. 5.

In this embodiment, the first mask layer 121 is, for example, a patterned photoresist having a first opening pattern exposing an upper surface of the temporary carrier board 110, i.e., exposing an upper surface of the metal seed layer 130.

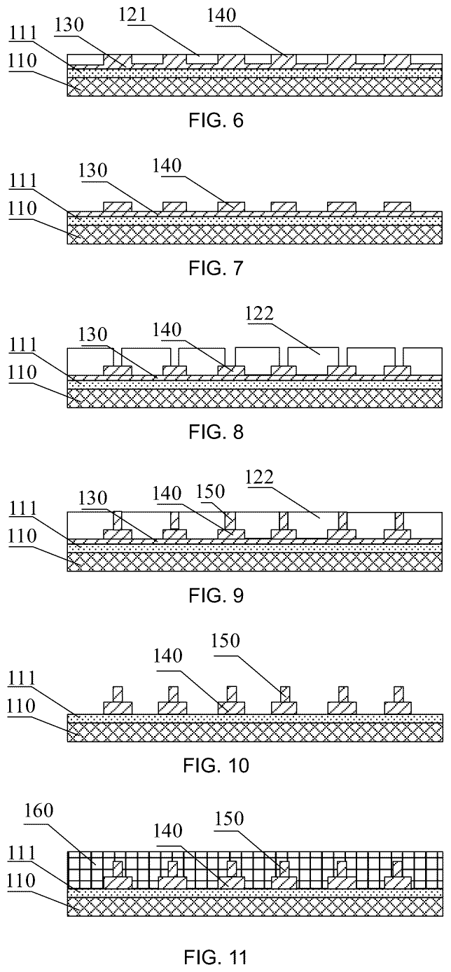

Step S12): forming a first metal pattern layer 140 based on the first opening graphic as shown in FIG. 6.

In this embodiment, the first metal pattern layer 140 is grown and formed by electroplating or chemical plating; in some embodiments, the first metal pattern layer 140 may also be formed by sputtering, deposition, etc., and accordingly, the upper surface of the temporary carrier board 110 will not need to be formed with the metal seed layer 130, i.e., step S10 is not required); wherein the first metal pattern layer 140 may be copper or other suitable metal.

Step S13): removing the first mask layer 121 as shown in FIG. 7 and forming a second mask layer 122 with a second opening pattern on the first metal pattern layer 140 as shown in FIG. 8, the second opening pattern exposing at least a portion of the upper surface of the first metal pattern layer 140.

In this embodiment, the first mask layer 121 may be removed by a process such as ashing, and the opening shape of the second mask layer 122 may be circular, oval, or the like.

Step S14): forming a first metal column layer 150 based on the second opening pattern as shown in FIG. 9.

In this embodiment, similar to the manner of forming the first metal pattern layer 140, the first metal column layer 150 is formed by growing the first metal column layer 150 by electroplating or chemical plating; the adoption of such an approach also requires the formation of a metal seed layer by sputtering or a suitable technique on the upper surface of the temporary carrier board 110 before forming the first mask layer 121, and then based on the first metal pattern layer exposed by the second mask layer 122, the first metal column layer 150 is formed by electroplating or chemical plating to grow and form the first metal column layer 150; in some embodiments, sputtering, deposition and the like may also be used to form the first metal column layer 150, and accordingly, when such an approach is used, the formation of the metal seed layer 130 on the upper surface of the temporary carrier board 110 is not required, i.e., step S10 is not required).

Step S15): removing the second mask layer 122 as shown in FIG. 10 and forming a first dielectric layer 160 on the upper surface of the temporary carrier board 110 as shown in FIG. 11, the first dielectric layer 160 encasing the metal pattern layer 140 and the metal post layer 150.

In this embodiment, the second mask layer 122 is removed by, for example, an ashing process; the first dielectric layer 160 may be formed by, for example, spin-coating, lamination, deposition, and the like; wherein the present embodiment grows and forms the first metal pattern layer 140 and the first metal column layer 150 by electroplating or chemical plating, and therefore, before the first dielectric layer 160 is formed, as shown in FIG. 10, it is also necessary to remove the metal seed layer 130 that is not covered by the first metal pattern layer 140 using a similar process such as flash etching.

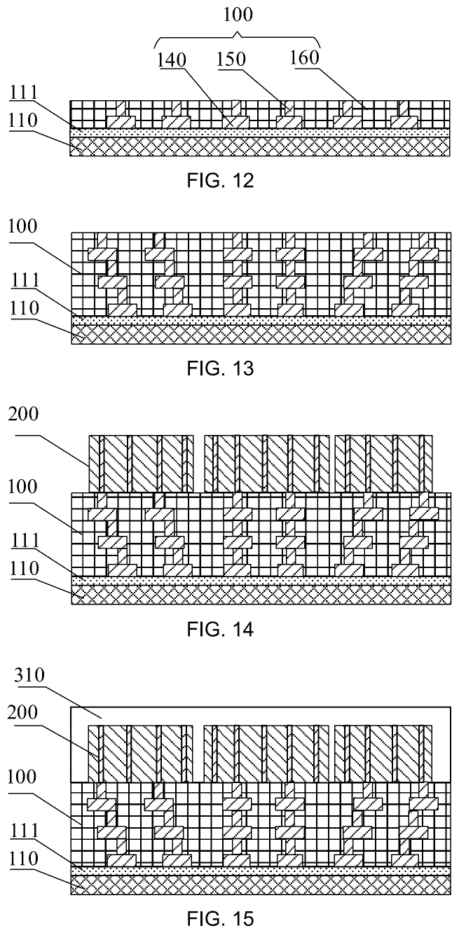

Step S16): grinding the first dielectric layer 160 until an upper surface of the first metal post layer 150 is exposed, as shown in FIG. 12.

In this embodiment, the first dielectric layer 160 may be ground and thinned using a chemical mechanical polishing (CMP) process. After grinding and polishing the first dielectric layer 160 flat, the subsequent process to form the metal pattern layer and metal column layer will not have a concave-convex condition, can make the metal pattern layer line flat, uniform, the formation of heavy wiring layer even if used in ultra-high-frequency components will not cause signal attenuation, loss.

Step S17): as shown in FIG. 13, step S11~S16 are repeated at least once to prepare and obtain multiple of the rewiring layer 100.

In this embodiment, steps S11~S16 can be repeated multiple times to complete the preparation of the multilayer rewiring layer 100, and each layer of the rewiring layer is first formed into a metal pattern layer, then a metal column layer is formed based on the metal pattern layer, and finally a dielectric layer is formed to cover the metal pattern layer and the metal column layer, and the dielectric layer is polished and sanded and flattened so as not to affect the flattening of the subsequent rewiring layer, which ultimately ensures that the connecting lines of the multilayer rewiring layer are flat. The dielectric layer is polished and flattened without affecting the flatness of the subsequent rewiring layers. As an example, as shown in FIG. 13, a multilayer rewiring layer having a 3-layer structure is shown.

Step S2): providing a plurality of TSV bridging substrates 200, bonding the plurality of the TSV bridging substrates 200 to the rewiring layer 100 as shown in FIG. 14.

In this embodiment, the TSV bridge substrate 200 has a number of pieces that are bonded to the rewiring layer 100, and the size and density of the silicon through holes TSV in each TSV bridge substrate 200 can be flexibly adjusted, and the density of the solder joints formed on the surface thereof can also be flexibly adjusted, so that for the logic chips, the TSV bridge substrate 200 with a high density of silicon through holes is used for interconnections, and for the storage chips, a lower density of silicon through holes is used for interconnections, and a lower density of silicon through holes is used for interconnections, so that multiple TSV bridge substrates are interconnected. For logic chips, the TSV bridge substrate 200 with high silicon through-hole density is used for interconnection, and for memory chips, the TSV bridge substrate 200 with lower silicon through-hole density is used for interconnection, so that the multiple TSV bridge substrates can be manufactured with higher yields and lower manufacturing costs as compared to interconnecting different kinds of heterogeneous chips through a whole piece of TSV intermediary layer substrate. It is noted that in some embodiments, after bonding a number of TSV bridge substrates 200 to the rewiring layer 100, a layer of material (not shown) is also required to be filled within the gaps where they are bonded together.

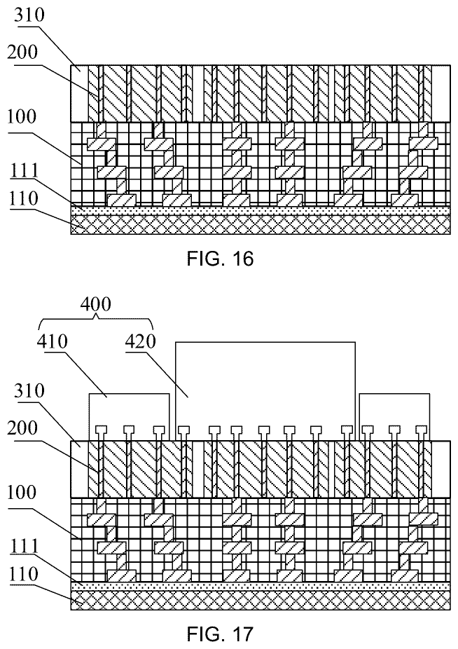

Step S3): forming a first plasticized sealing layer 310 on the upper surface of the rewiring layer 100, polishing the first plasticized sealing layer 310 exposes the solder joints of the TSV bridging substrate 200, as shown in FIGS. 15 and 16.

In this embodiment, first, as shown in FIG. 15, a first plasticized sealing layer 310 is formed on the upper side of the rewiring layer 100, and the first plasticized sealing layer 310 wraps around the TSV bridging substrate 200; then, as shown in FIG. 16, the first molding layer 310 is thinned until the upper surface of the TSV bridging substrate 200 is revealed. Wherein, the methods of forming the first plasticized sealing layer 310 include, but are not limited to, compression molding, molding, liquid seal molding, vacuum laminating, and spin-coating, and the materials thereof include, but are not limited to, polyimide, silicone, and epoxy; and the methods of thinning the first plasticized sealing layer 310 include, but are not limited to, a grinding process (i.e., backside grinding).

Step S4): providing a plurality of chips 400, bonding the plurality of the chips 400 to the plurality of the TSV bridge substrates 200, as shown in FIG. 17.

In this embodiment, the chip 400 provided may be either a bare chip or a preliminary packaged chip; the number of the chips 400 shall be at least two, and typically, greater than or equal to three; and, the chip 400 may be a dedicated integrated circuit (ASIC) chip, an analog chip, a sensor chip, a wireless and RF chip, a voltage regulator chip, or a memory chip, with the different types of chips typically have different process accuracies and different densities and diameter sizes of surface pads. The present embodiment takes two types of chips as examples, as shown in FIG. 1, the first type of chip 410 has a higher density of active surface solder joints and a smaller diameter of solder joints compared to the second type of chip 420; therefore, the TSV bridging substrate 200 bonded and connected with the first type of chip 410 has a higher density of silicon through holes and a smaller diameter of surface solder joints, and it is more difficult to fabricate, and the cost is higher; the TSV bridging substrate 200 bonded and connected with the second type of chip 420 bonded with the second type of chip 200 has a relatively lower density of silicon through holes, a relatively larger diameter of surface solder joints, a lower production difficulty, and a lower cost. Multiple smaller TSV bridge substrates 200, as opposed to interconnecting through a whole TSV bridge substrate 200, allows for flexibility in adjusting the process precision, improving yields, and reducing costs. It is noted that in some embodiments, after bonding the plurality of chips 400 to the plurality of TSV bridge substrates 200, a layer of material (not shown) is also required to be filled within the gap where they are bonded together.

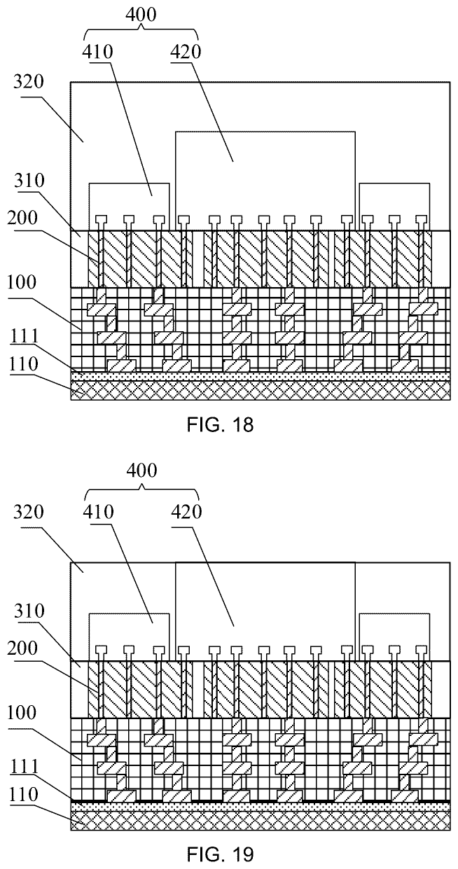

Step S5): forming a second plasticized layer 320 on the upper surface of the first plasticized layer as shown in FIG. 18.

In this embodiment, the method of forming the second plasticized sealing layer 320 is the same as the method of forming the a first plasticized sealing layer 310, and it should be noted that it is possible to choose to thin the Second plasticized sealing layer 320 to a certain thickness in order to meet the thickness requirements of the three-dimensional package structure, or it is possible to choose not to thin the second plasticized sealing layer 320; as shown in FIG. 19, in this embodiment, thinning the second plasticized sealing layer 320 so that it is exposed to the upper surface of the second type chip's upper surface.

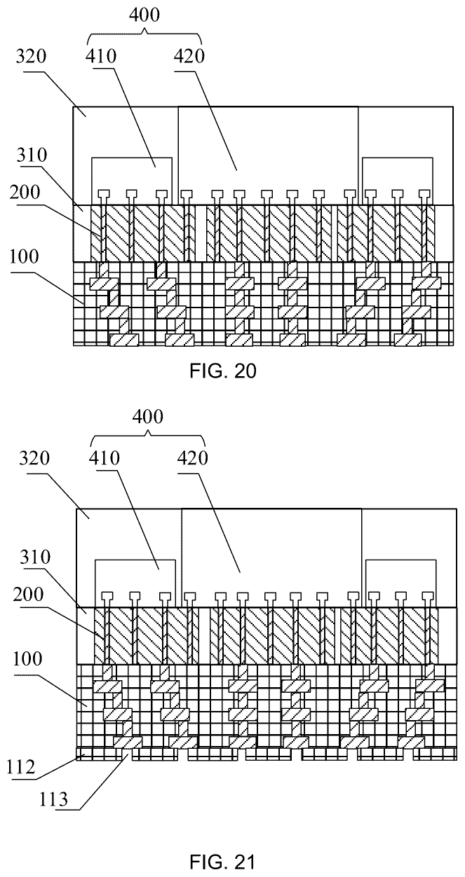

Step S6): removing the temporary carrier board 110, forming a rewiring layer solder joint 101 on a surface of the rewiring layer 100 away from the TSV bridging substrate 200, as shown in FIGS. 20 to 23.

In this embodiment, firstly, as shown in FIG. 20, heating and/or light means can be used to reduce the stickiness of the release layer 111 and remove the temporary carrier board 110, and then, processing methods such as tearing, light, etc., can be used to peel off the release layer 111; of course, a laser peeling process can also be directly used to peel off the laser peeling and the rewiring layer 100 from each other, and the laser peeling process directly vaporizes the release layer 111 vaporized to achieve the effect of peeling off the temporary carrier board 110 from the rewiring layer 100, which is processed with high precision and with less impurities remaining.

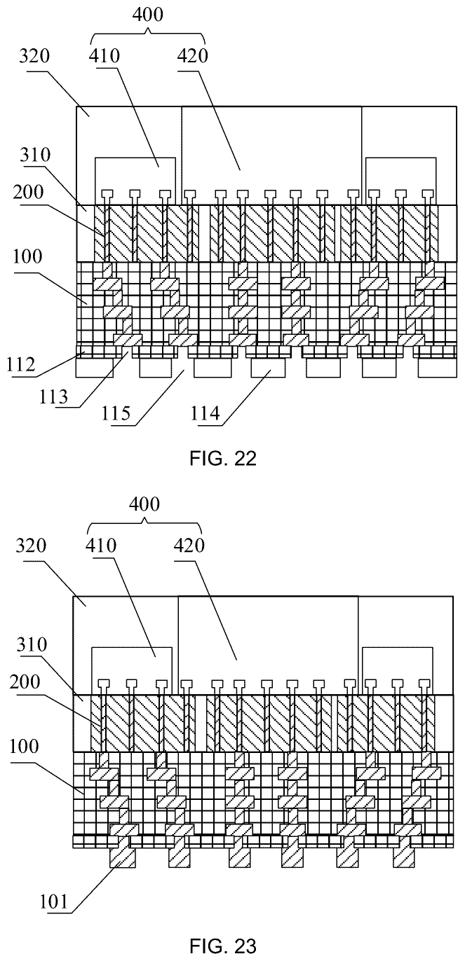

In forming the rewiring layer solder joints 101, as shown in FIG. 21, a protective layer 112 may first be formed on the lower surface of the rewiring layer 100 (the side away from the TSV bridging substrate 200), wherein the protective layer 112 may be made of silicon oxide, silicon nitride, silicon oxynitride, or a combination thereof, and then, a laser drilling process, an exposure and development process, a photolithography and etching process, or a combination thereof, may be used within the protective layer to a window 113 is formed, after which, as shown in FIG. 22, a solder joint mask layer 114 having an opening 115 is formed in the protective layer, and the opening 115 is overlapped with the window 113 to expose the first metal pattern layer 140 within the rewiring layer 100, and finally, as shown in FIG. 23, a rewiring layer solder joint 101 is formed within the opening 115 and the window 113, and the material of the rewiring layer solder joint 101 comprises copper, aluminum, a lead free lead alloy (e.g., an alloy of gold, tin, silver, aluminum, or copper), or a lead alloy (e.g., a lead-tin alloy). The rewiring layer solder joint 101 may be a conductive bump, C4 (controlled collapse chip connection, C4) bump, solder ball, and other structures.

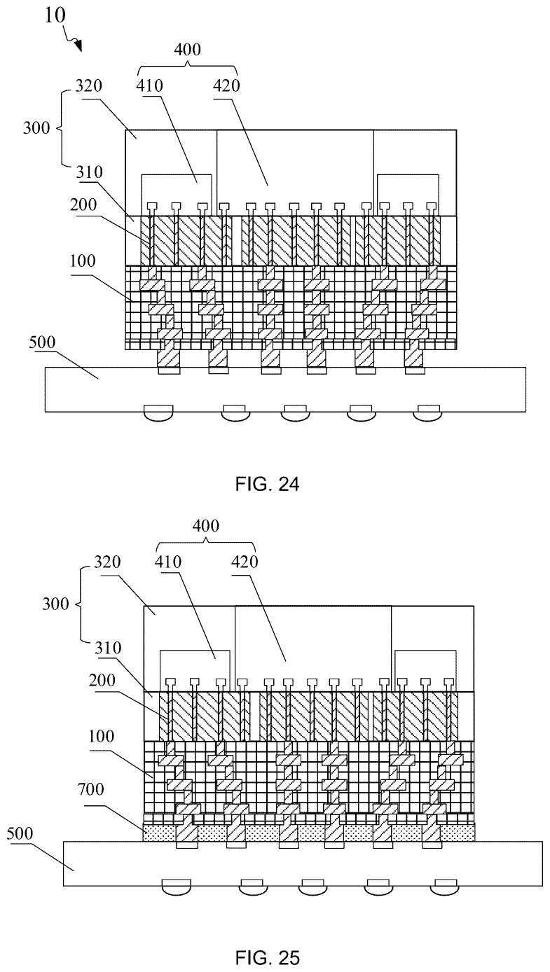

Step S7): as shown in FIG. 24, a package substrate 500 with a package substrate is provided and the rewiring layer 100 is bonded to the package substrate 500 through the package substrate and the rewiring layer solder joints.

In this embodiment, the bonding connection between the rewiring layer 100 and the package substrate 500 can be realized by ultrasonic bonding, thermocompression bonding or thermos-sonic bonding, etc., and the bonded structure is the three-dimensional encapsulation structure 10.

In some embodiments, after bonding the rewiring layer 100 to the package substrate 500, as shown in FIG. 25, it is also necessary to fill a filler material layer 300 within the gap wherein the rewiring layer 100 is bonded to the package substrate 500. It should be noted that due to the inversion, the upper and lower positional relationships of the interlayer structures within the three-dimensional encapsulated structure 10 are changed accordingly, and the resulting qualification regarding the positional relationships is subject to inconsistencies in the foregoing and foregoing descriptions, and should be understood.

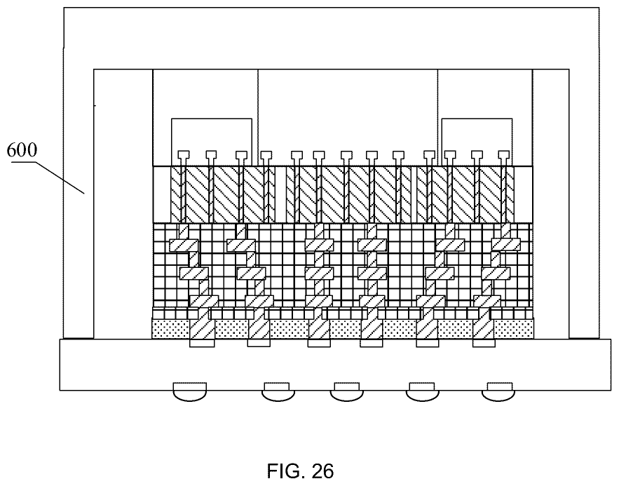

Step S8): as shown in FIG. 26, a heat sink 600 is provided on top of the package substrate 500, wherein the heat sink 600 encases a number of the chips 400 therein.

In this embodiment, the heat sink plate 600 conducts the heat generated by the chip to be dispersed.

Accordingly, this embodiment also provides a three-dimensional packaging structure 10, as shown in FIG. 24, the three-dimensional packaging structure 10 comprising: a packaging substrate 500, a rewiring layer 100, a plurality of TSV bridging substrates 200, a plurality of chips 400, and a layer of laminate material 300, wherein the rewiring layer 100 is disposed on an upper surface of the packaging substrate 500, and is by bonding coupled with the packaging substrate 500 bonded to the package substrate 500; the plurality of TSV bridging substrates 200 are disposed on an upper surface of the rewiring layer 100, which are bonded to the rewiring layer 100; the plurality of chips 400 are disposed on an upper surface of the TSV bridging substrates 200, which are bonded to the TSV bridging substrates 200; the laminate material layer 300 is formed on an upper surface of the rewiring layer 100, which encapsulates the plurality of the TSV bridging substrate 200 and the plurality of the chips 400.

In this embodiment, the encapsulation substrate 500, the rewiring layer 100, the TSV bridging substrate 200, and the chip 400 are stacked in order from bottom to top, and each layer is connected to each other by bonding; the wiring density of the encapsulation substrate 500 is lower than that of the rewiring layer 100, the wiring density of the rewiring layer 100 is lower than that of the TSV bridging substrate 200, and several heterogeneous chips 400 communicate with each other through multiple TSV bridging substrates 200 with different wiring densities. 400 communicate with each other through the plurality of TSV bridging substrate 200 with different wiring densities, the line is short, the communication quality is excellent, the yield can be increased, and the production cost can be reduced; TSV bridging substrate 200 is electrically connected to the encapsulation substrate 500 through the rewiring layer 100, and the rewiring layer 100 serves as a buffer structure between the two, replacing a part of the encapsulation substrate 500's electric connection function, making the encapsulation substrate 500 The electrical signal transmission can be completed without preparing more layers, which reduces the preparation cost of the multilayer packaging substrate.

Specifically, the three-dimensional encapsulation structure further comprises a filler material layer 300 and a heat sink plate 600, as shown in FIG. 25, wherein the filler material layer 300 is formed within a gap wherein the plurality of the TSV bridging substrate 200 is by bonding connected to the rewiring layer 100, the plurality of the chips 400 are by bonding connected to the plurality of the TSV bridging substrate 200, and the plurality of the rewiring layers 100 are by bonding connected to the packaging substrate 500; as shown in FIG. 26, the heat sink plate 600 is provided on an upper surface of the packaging substrate 500; a heat sink 600 is provided on an upper surface of the package substrate 500 as shown in FIG. 26.

In this embodiment, the material of the filler material layer 300 includes, but is not limited to, epoxy resin. The filler material layer 300 protects the rewiring layer 100 from the environment, reduces the effects of thermal expansion mismatch between the rewiring layer 100 and the package substrate 500, and allows the reliability of the assembly to be greatly improved. Heat sink 600 conducts and dissipates heat for chip 400.

In summary, the three-dimensional package structure of the present invention and its preparation method use several smaller TSV bridge substrates instead of the whole TSV intermediate layer substrate to realize high-density interconnection between different chips, and on the basis of not affecting the interconnection function, it can increase the fabrication yield of the intermediate layer substrate and reduce the cost; the intermediate layer substrate of high connectivity density is connected with the medium connectivity density rewiring layer first, then the rewiring layer connects with a lower density package substrate. High connection density intermediary layer substrate is first connected with medium connection density heavy wiring layer, and then the heavy wiring layer is connected with lower density package substrate, which reduces the number of interconnection layers inside the package substrate, and avoids the risk of low yield of multi-layer substrate production; the new process of producing heavy wiring layer, the flatness of the heavy wiring layer formed by production is good, and the reliability of the signal transmission is high.

The foregoing embodiments are only illustrative of the principles of the present invention and its efficacy and are not intended to limit the invention. Any person skilled in the art may modify or change the above embodiments without violating the spirit and scope of the present invention. Accordingly, all equivalent modifications or alterations accomplished by persons having ordinary knowledge in the art without departing from the spirit and technical ideas disclosed herein shall still be covered by the claims of the present invention.

1. A method of preparing a three-dimensional encapsulated structure comprising steps of:
S1: providing a temporary carrier board and preparing a rewiring layer on an upper surface of the temporary carrier board;
S2: providing a plurality of TSV bridging substrates and bonding the plurality of TSV bridging substrates to the rewiring layer;
S3: forming a first plasticized layer on an upper surface of the rewiring layer, wherein the first plasticized layer exposes tops of the plurality of TSV bridging substrates;
S4: providing a plurality of chips and bonding the plurality of the chips to the plurality of the TSV bridging substrates;
S5: forming a second plasticized layer on an upper surface of the first plasticized layer;
S6, removing the temporary carrier board and forming a rewiring layer solder joint on a surface of the rewiring layer away from the plurality of TSV bridge substrates; and
S7: providing a package substrate and bonding the rewiring layer to the package substrate through the rewiring layer solder joint.

2. The method of preparing the three-dimensional encapsulated structure according to claim 1, wherein the step of preparing the rewiring layer in S1 comprises:
S11: forming a first mask layer having a first opening pattern on the upper surface of the temporary carrier board;
S12: forming a first metal pattern layer based on a first opening pattern;
S13: removing the first mask layer and forming a second mask layer having a second opening pattern on the first metal pattern layer, wherein the second opening pattern exposes at least a portion of an upper surface of the first metal pattern layer;
S14: forming a first metal column layer based on the second opening pattern;
S15: removing the second mask layer and forming a first dielectric layer on the upper surface of the temporary carrier board, wherein the first dielectric layer encompasses the first metal pattern layer and the first metal column layer; and
S16: grinding the first dielectric layer until an upper surface of the first metal column layer is exposed.

3. The method of preparing the three-dimensional encapsulated structure according to claim 2, wherein the step of preparing the rewiring layer further comprises: s17, repeating steps S11~S16 at least once to prepare and obtain multiple of the rewiring layers.

4. The method of preparing the three-dimensional encapsulated structure according to claim 2, wherein, before S11, the step of preparing the rewiring layer further comprises a step of S10: forming a metal seed layer on the upper surface of the temporary carrier board; wherein the method further comprises, after removing the second mask layer in S15, before forming the first dielectric layer, a step of removing the portion of the upper surface of the first metal pattern layer exposed by the second opening pattern, as well as removing the metal seed layer exposed from the first metal pattern layer.

5. The method of preparing the three-dimensional encapsulated structure according to claim 1, further comprising: a step of forming a release layer on the upper surface of the temporary carrier board before forming the rewiring layer on the upper surface of the temporary carrier board in S1; and a step of removing the release layer after removing the temporary carrier board in S6.

6. The method of preparing the three-dimensional encapsulated structure according to claim 1, wherein
S2 further comprises, after bonding the plurality of the TSV bridging substrates to the rewiring layer, a step of filling a laminate layer into a gap between the plurality of the TSV bridging substrates bonded to the rewiring layer;
S4 further comprises, after bonding the plurality of chips to the plurality of the TSV bridging substrates, a step of filling a laminate layer into a gap between the plurality of chips and the plurality of the TSV bridging substrates; and
S7 further comprises, after bonding the rewiring layer to the package substrate, a step of filling a laminate layer into within a gap between the rewiring layer and the package substrate.

7. The method of preparing the three-dimensional encapsulated structure according to claim 1, further comprising a step S8, providing a heat sink on a surface of the package substrate connected with the rewiring layer, wherein the heat sink encases the plurality of the chips therein.

8. A three-dimensional encapsulation structure comprising:
a packaging substrate, a rewiring layer, a plurality of TSV bridging substrates, a plurality of chips and a laminate layer; wherein
the rewiring layer is disposed and bonded on an upper surface of the package substrate;
the plurality of the TSV bridging substrates is disposed and bonded on an upper surface of the rewiring layer;
the plurality of chips is disposed and bonded on upper surfaces of the plurality of the TSV bridging substrates; and
the laminate layer is formed on the upper surface of the rewiring layer which encases the plurality of the TSV bridge substrates and the plurality of the chips.

9. The three-dimensional encapsulation structure according to claim 8, further comprising a heat sink plate, provided on the upper surface of the packaging substrate, encapsulating the plurality of the chips therein.

10. The three-dimensional encapsulation structure according to claim 8, further comprising a laminate layer formed into a gap between the plurality of the TSV bridging substrates bonded to the rewiring layer, the plurality of the chips bonded to the plurality of the TSV bridging substrates, and a gap between the rewiring layer bonded to the packaging substrate.
